(19) United States
(12) Patent Application Publication
(10) Pub. No.: US 2011/0235290 A1
(43) Pub. Date: Sep. 29, 2011

(54) ELECTRICAL CIRCUIT ASSEMBLY, CONTROL DEVICE AND METHOD FOR PRODUCING AN ELECTRICAL CIRCUIT ASSEMBLY

(75) Inventors: Volker Luhr, Markgroeningen (DE); Markus-Alexander Schweiker, Buehlertal (DE); Rene Kloetzig, Reutlingen (DE); Andrea Voeth, Hemmingen (DE)

(73) Assignee: ROBERT BOSCH GMBH, Stuttgart (DE)

(21) Appl. No.: 13/133,283

(22) PCT Filed: Nov. 25, 2009
(86) PCT No.: PCT/EP09/65821

§ 371 Date: Jun. 7, 2011

(30) Foreign Application Priority Data
Dec. 8, 2008 (DE) 10 2008 054 385.3

(51) Int. Cl. H05K 5/00; H05K 3/36; H05K 7/10

(52) U.S. Cl. 361/752; 29/830; 361/767; 361/771

(57) ABSTRACT

The invention relates to an electrical circuit assembly (1), particularly for a control device of a motor vehicle, having a first circuit board (2), at least one second circuit board (3) and at least one holder (4) for holding the second circuit board (3) on the first circuit board (2), producing an electrical contact (6) between the first (2) and the second (3) circuit boards. According to the invention, the second circuit board (3) is preassembled on the holder (4) and the preassembled unit (5), comprising the second circuit board (3) and holder (4), is connected to the first circuit board (2), wherein the holder (4) and the second circuit board (3) are arranged crosswise, particularly at a right angle, to the first circuit board (2). The invention furthermore relates to a control device and to a method for producing an electrical circuit assembly (1).

### BACKGROUND OF THE INVENTION

The invention relates to an electrical circuit assembly, in particular for a control device of a motor vehicle, comprising a first circuit board, at least one second circuit board and at least one mount for holding the second circuit board on the first circuit board whilst producing an electrical contact between the first and the second circuit board. The invention also relates to a control device comprising at least one electrical circuit assembly. The invention furthermore relates to a method for producing an electrical circuit assembly.

Electrical circuit assemblies of the type mentioned in the introduction are known from the prior art. By way of example, DE 692 10 365 T2 describes an electrical connector corresponding to the mount, by means of which connector printed circuit boards, for example, in other words circuit boards, can be electrically connected to one another. In this case, the first circuit board is a memory control board and the second circuit board is a single inline memory module (SIMM). The memory module is intended to be arranged perpendicularly with respect to the surface of the memory control board by means of the electrical connector. Contact connections to which the memory module is electrically connected in the inserted state are arranged in a slot of the electrical connector. The electrical contact between the memory module and the memory control board is produced via the contact connections. In the case of this assembly, provision is made for fixedly connecting the electrical connector to the memory control board, while the memory module can be inserted into the connector and can also be removed again from the latter. It is therefore provided that the electrical connector is designed for changing the memory module, while it always remains fixedly connected to the memory control board. It is often desirable, however, in particular in the case of control devices for motor vehicles, simultaneously to arrange a plurality of second circuit boards on the first circuit board and to produce the electrical contact between the first and the second circuit boards. In addition, often the second circuit board is intended already to be incorporated in a housing of the electrical circuit assembly before the first circuit board is inserted into said housing. For this reason, it is necessary to provide the second circuit board with a sufficient mechanical strength and, moreover, to equip it with a mount, by means of which it can be arranged in a positionally fixed manner in the housing in order to be able reliably to produce the electrical contact between the first and the second circuit board as soon as the former is inserted into the housing. That means that in many cases a permanent connection between the first circuit board and the mount and/or the second circuit board is not intended to be produced.

### SUMMARY OF THE INVENTION

By comparison with the electrical circuit assembles known from the prior art, the electrical circuit assembly of the invention has the advantage that it increases the strength of the second circuit board, enables the latter to be fixed in a housing and can be embodied in such a way that there is no permanent electrical contact between the first and the second circuit board. This is achieved according to the invention by virtue of the fact that the second circuit board is preassembled on the mount, and the preassembled unit consisting of second circuit board and mount is connected to the first circuit board, wherein the mount and the second circuit board are arranged transversely, in particular at right angles, with respect to the first circuit board. Therefore, in contrast to the electrical circuit assemblies known from the prior art, it is not the case that firstly the mount is fixed on the first circuit board and then the second circuit board is inserted into the mount. Rather, it is provided that firstly the second circuit board is connected to the mount, such that the preassembled unit is present. The mount thus serves for increasing the strength of the second circuit board and the fixing of the second circuit board on a housing on or in which the electrical circuit assembly is provided. Afterward, the preassembled unit consisting of second circuit board and mount is connected to the first circuit board. The electrical contact between the first and the second circuit board is produced in this case. Both the mount and the second circuit board are intended to be arranged transversely with respect to the first circuit board. A right-angled arrangement is advantageously provided. The fixing of the preassembled unit on the first circuit board can be provided by means of the second circuit board, the mount or both. By way of example, contact elements of the second circuit board can be connected to the first circuit board, wherein the mount serves for support on the first circuit board. The electrical contact between the first and the second circuit board can be produced both directly and indirectly. In the former case, contact elements of the second circuit board are connected to contact elements of the first circuit board while in the latter case the mount likewise has contact elements that are connected to the contact elements of both the first and the second circuit boards.

One development of the invention provides for the preassembled unit to be connected to the first circuit board in a releasable manner. Consequently, there is no need for there to be a permanent connection between the preassembled unit, that is to say the second circuit board and/or the mount, and the first circuit board. Rather, it is provided that the preassembled unit, after having been connected to the first circuit board, is releasable again therefrom.

One development of the invention provides for the connection between the first circuit board and the mount and/or the fixing of the second circuit board to the mount to be produced by means of hot calking, screwing, clipping or press-fitting. Both for the connection between the first circuit board and the mount and the fixing of the second circuit board on the mount, it is possible to provide connections which are designed to be releasable—for example screwing, clipping or press-fitting—or permanent—for example hot calking In this case, the material of the first and of the second circuit board and of the mount is provided accordingly.

One development of the invention provides for the mount to be a die-cast component. The mount is particularly advantageous and cost-effective in terms of production if it is embodied as a die-cast component. During production in the die-casting method, holding elements of the mount can already be concomitantly formed. In this way, the mount can be produced in just one production step.

One development of the invention provides for the mount to comprise aluminum, zinc or magnesium or a plastic. The mount can be produced from aluminum, zinc or magnesium or comprise these substances, for example in the form of an alloy. The mount can also be produced from a plastic. These materials can be processed particularly advantageously in the die-casting method. It is advantageous if the materials have a good thermal conductivity in order that heat possibly arising at the second circuit board can be dissipated from the latter. Given an appropriate choice of material, therefore, the mount can also serve as a cooling device for the second circuit board.

One development of the invention provides a housing, in which the first circuit board, the second circuit board and/or the mount are arranged at least in regions. In this case, by way of example, one or a plurality of second circuit boards with mount can be arranged in the housing and subsequently connected to the first circuit board. On the other hand, it is also possible firstly to fix the first circuit board in the housing and then to introduce the second circuit board into said housing. In this case, it is not necessary for the first circuit board, the second circuit board and/or the mount to be arranged completely in the housing. Rather, they can also be provided outside the housing in regions. By way of example, the housing can have cutouts through which the second circuit board together with the mount are introduced into said housing and thus connected to the first circuit board. However, it can also be provided that the housing completely envelopes the first circuit board, the second circuit board and the mount and in this case is embodied as water-tight, in particular.

One development of the invention provides for the mount to be fixed together with the second circuit board on/in a housing. In other words, it is possible firstly to arrange the second circuit board together with the mount in the housing. In this case, a connection to, or an electrical contact with, the first circuit board is not yet necessary. This will be produced only at a later point in time.

One development of the invention provides for the preassembled unit to be fixed on/in the housing by means of screwing, clamping or adhesive bonding. The mount with second circuit board preassembled thereon, that is to say the preassembled unit, can be fixed on the housing in various ways. By way of example, releasable connections, such as screwing or clamping, but also permanent connections, such as adhesive bonding, for example, are provided. The fixing can be present either between the housing and the mount or between the housing and the second circuit board or both.

One development of the invention provides for at least two mounts to be provided, which are arranged at an angle with respect to one another. In this case, the at least two mounts can be embodied as an angle element, for example. That means that the mounts are either connected to one another via a holding element or embodied in one piece. Preferably, the mounts are in this case tilted about their vertical axis with respect to one another. The angle is therefore not equal to 0°, preferably equal to 90°. The mounts can either be connected to one another via the holding element or have connecting elements by means of which they can be fixed to one another.

One development of the invention provides for the electrical contact between the first and the second circuit board to be produced directly and/or via the mount. After the preassembled unit has been connected to the first circuit board, therefore, an electrical connection can be present directly between the first and second circuit boards. For this purpose, by way of example, both the first and the second circuit boards have contact elements which form the electrical contact after connection. It can also be provided that further contact elements are provided on/in the mount, which are connected both to contact elements of the first circuit board and to contact elements of the second circuit board and thus produce the electrical contact indirectly via the mount. In this case, the electrical contact between the second circuit board and the mount can be formed as early as after the preassembly of the preassembled unit, while the electrical contact with the first circuit board only arises with the connection of the preassembled unit to the first circuit board.

One development of the invention provides for the direct contact to be produced by means of a semi flexible connection, at least one press-fit pin, at least one spring element, a circuit board connector and/or soldering. Therefore, the electrical contact is also provided either via releasable or via unreleasable connections. One example of a releasable connection is the at least one spring element, for example an S spring element, and one example of an unreleasable connection is soldering. If the preassembled unit is intended to be arranged in the housing before the first circuit board, then it is recommended to produce the direct contact via the at least one press-fit pin or the at least one spring element. These connections can be produced by simply press-fitting or placing the first circuit board onto the contact elements of the second circuit board.

One development of the invention provides for the contact via the mount to be produced via at least one contact element. On or in the mount, therefore, at least one contact element is provided which, after preassembly and connection of the preassembled unit to the first circuit board, has an electrical contact both the first and with the second circuit board. Consequently, the first and the second circuit boards are then also electrically connected to one another.

One development of the invention provides for the contact element to make contact with the first circuit board by means of at least one spring element or at least one press-fit pin and with the second circuit board by means of at least one press-fit pin. The electrical contact with the second circuit board is therefore produced by means of the at least one press-fit pin. In this case, the press-fit pin can be designed such that it simultaneously serves for holding the second circuit board on the mount; in other words, the preassembly is realized by means of said pin. For making contact with the first circuit board, the mount has at least one spring element, for example an S spring element, or at least one press-fit pin. In this case, the spring element ensures simple demounting of the mount from the first circuit board if the connection between them is intended to be released. Both the spring element and the press-fit pin can consist of gold or comprise gold, that is to say be gold-plated.

The invention furthermore relates to a control device comprising at least one electrical circuit assembly in accordance with the above embodiments.

The invention also relates to a method for producing an electrical circuit assembly, in particular in accordance with the above embodiments, wherein the circuit assembly has a first circuit board, at least one second circuit board and at least one mount for holding the second circuit board on the first circuit board whilst producing an electrical contact between the first and the second circuit board. In this case, it is provided that the second circuit board is preassembled on the mount, and that the preassembled unit consisting of second circuit board and mount is connected to the first circuit board, wherein the mount and the second circuit board are arranged transversely, in particular at right angles, with respect to the first circuit board.

### BRIEF DESCRIPTION OF THE DRAWINGS

The invention is explained in greater detail below on the basis of the exemplary embodiments illustrated in the drawing, without the invention being restricted. In the figures:

FIG. 1 shows an electrical circuit assembly comprising a first circuit board, a second circuit board and a mount,

FIG. 2 shows a detail view of a preassembled unit consisting of the mount and the second circuit board,

FIG. 3 shows an arrangement composed of two mounts which are connected to one another and are arranged at an angle with respect to one another,

FIG. 4 shows a housing of the electrical circuit assembly, wherein two preassembled units are provided,

FIG. 5 shows a view of the housing with two preassembled units arranged therein, and the first circuit board which is to be inserted into the housing,

FIG. 6 shows an exploded drawing of the electrical circuit assembly comprising the housing, the preassembled units, the first circuit board and screws used for closing the housing,

FIG. 7 shows a detail view of the mount, wherein press-fit pins are provided for making contact with the second circuit board and S spring elements are provided for making contact with the first circuit board,

FIG. 8 shows the mount known from FIG. 7 in a view from below, such that contact areas for the S spring elements can be discerned, and

FIG. 9 shows a mount, wherein press-fit pins are provided for making contact both with the first and with the second circuit board.

### DETAILED DESCRIPTION

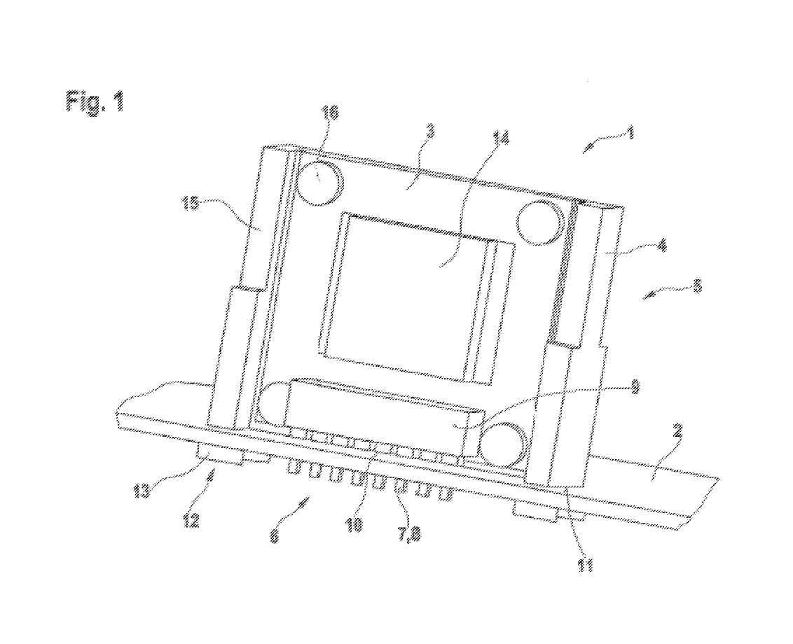

FIG. 1 shows an electrical circuit assembly 1 consisting of a first circuit board 2, a second circuit board 3 and a mount 4. The second circuit board 3 is preassembled on the mount 4, thus resulting in a preassembled unit 5. In this case, the second circuit board 3 is fixed to the mount 4 for example by means of hot calking, screwing, clipping or press-fitting. Both the second circuit board 3 and the mount 4 are arranged at right angles with respect to the first circuit board 2, that is to say that a vertical axis of the mount 4 is perpendicular to the first circuit board 2. In the example illustrated in FIG. 1, an electrical contact 6 is produced directly between the first circuit board 2 and the second circuit board 3 by means of contact elements 7. The contact elements are embodied as press-fit pins 8 and arranged by means of a contact element holder 9 such that when the preassembled unit 5 is connected to the first circuit board 2, the pressfit pins 8 can be pressed through contact cutouts 10 in the first circuit board 2. The mount 4 forms contact areas 11 on its side that comes into contact with the first circuit board 2, said contact areas serving to stabilize the second circuit board 3. After the preassembled unit 5 has been connected to the first circuit board 2, the contact areas 11 ensure that no tilting of the preassembled unit 5 or of the second circuit board 3 can occur. The connection between the preassembled unit 5 and the first circuit board 2 can be produced via the press-fit pins 8, for example.

In addition, in the example illustrated in FIG. 1, however, latching devices 12 are provided, which, with latching heads 13, extend through latching cutouts (not visible here) in the first circuit board 2 upon the connection of the preassembled unit 5 to the first circuit board 2, and produce a latching connection between the preassembled unit 5 and the first circuit board 2. At least one electrical component 14 is provided on the second circuit board 3 and is electrically connected thereto, that is to say can be in electrical contact with the first circuit board 2. The mount 4 substantially consists of two holding arms 15 which are connected to one another and which run parallel to the second circuit board 3. The latching devices 12 are provided on the holding arms 15. At the same time, the holding arms 15 can also have at least one insert (not illustrated here) for the second circuit board 3, into which the latter can be inserted for preassembly. In the example illustrated, however, the preassembly is effected by means of holding elements 16, which can be embodied analogously to the latching devices 12, for example, and hold the second circuit board 3 on the mount 4. Both the latching devices 12 and the holding elements 16 can be embodied, for example, as latching connection elements which can be latched in the mount 4. That means that they have, in the part engaging into the mount 4, latching elements that securely hold them in said part after insertion.

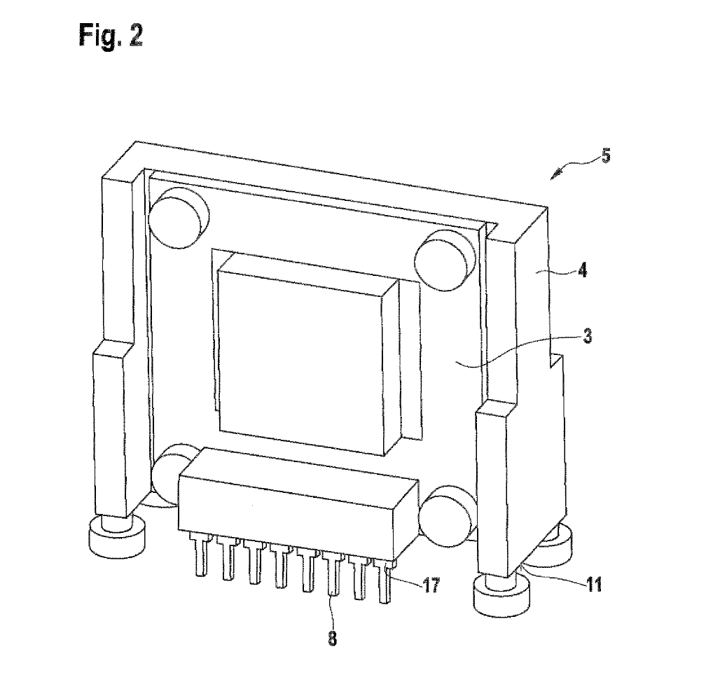

FIG. 2 shows the preassembled unit 5 consisting of mount 4 and second circuit board 3 without the first circuit board 2 illustrated in FIG. 1. It can clearly be discerned that the press-fit pins 8 have a collar 17, which serves together with the contact area 11 for insert delimitation during the connection of the preassembled unit 5 to the first circuit board 2. During connection, therefore, both the contact area 11 and the collar 17 can be connected to the first circuit board 2.

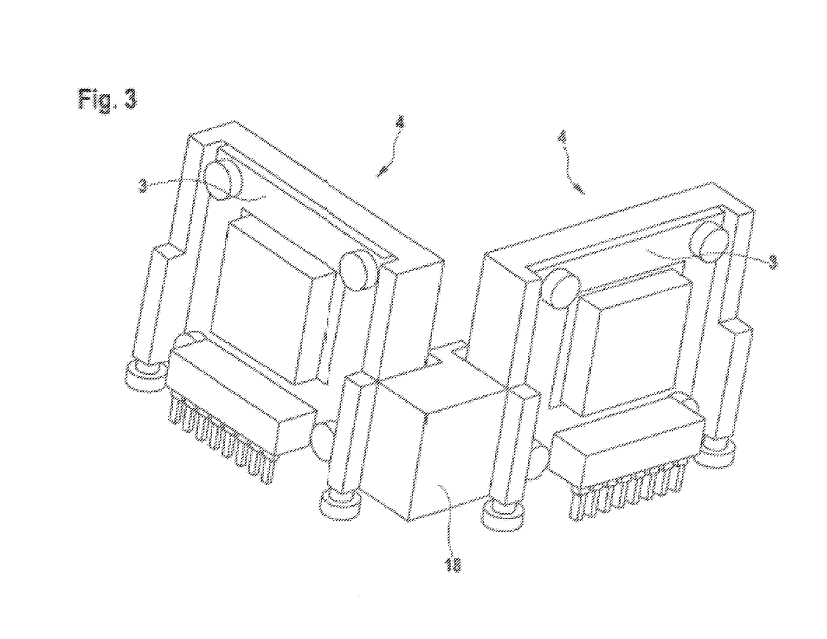

FIG. 3 shows two mounts 4, on each of which a second circuit board 3 is preassembled. The mounts 4 are arranged perpendicularly to one another and are connected to one another—in particular in a releasable manner—by means of a connecting element 18. The mounts 4 connected to one another by means of the connecting element 18 can therefore be jointly connected to the first circuit board 2. Alternatively, it can also be provided that the mounts 4 are fixed to one another without the connecting element 18, that is to say directly. By way of example, the mounts 4 can be embodied in one piece, in particular during a common production process.

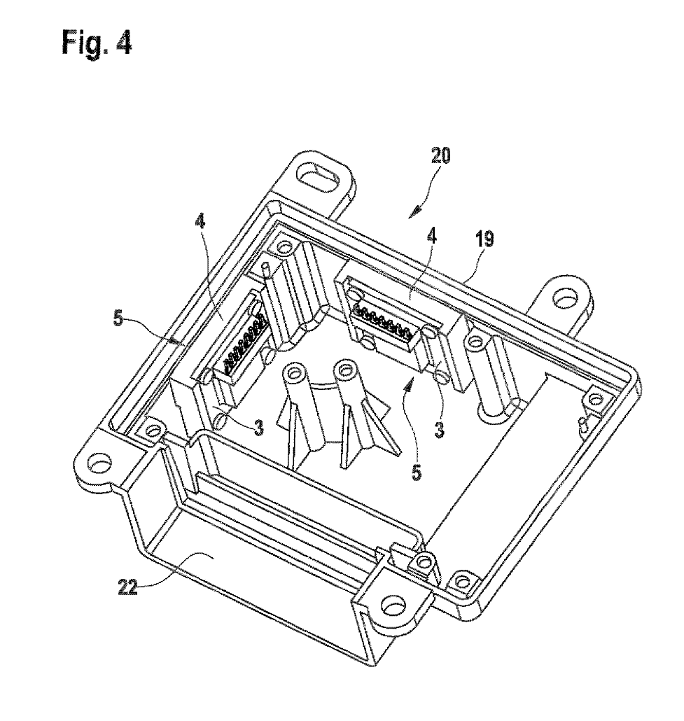

FIG. 4 shows a first part 19 of a housing 20, in which two mounts 4 with second circuit board 3 preassembled therein are arranged. The first part 19 of the housing 20 is embodied as a shell and can be closed by means of a second part 21 (not illustrated here), after the connection of the preassembled units 5 to the first circuit board 2 (likewise not illustrated here). In a front side of the housing 20, a cutout 22 is provided in which, for example, a male connector strip of the first circuit board 2 can be arranged. In the example illustrated, the preassembled units 5 are fixed in the housing 20 by means of clamping.

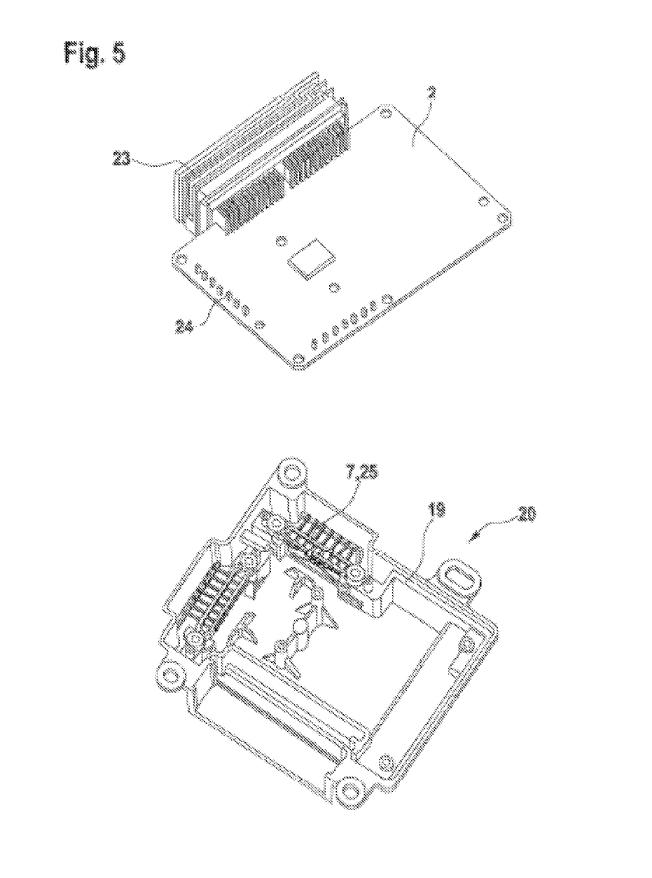

FIG. 5 shows that the first part 19 of the housing 20 and the first circuit board 2 with male connector strip 23 fitted therein. The first circuit board 2 can be arranged in the housing 20 in such a way that the male connector strip 23 is located in the cutout 22. In this case, an electrical contact is produced between contact elements 24 of the first circuit board 2 and the contact elements 7, which are embodied here as contact areas 25 for S spring elements. Consequently, after the positioning of the first circuit board 2 in the housing 20, the first circuit board 2 and the second circuit board 3 are electrically connected to one another. By virtue of the production of the electrical contact 6 by means of the S spring elements and the contact areas 25—which form a releasable connection—the first circuit board 2 can be removed from the housing 20 again in a simple manner.

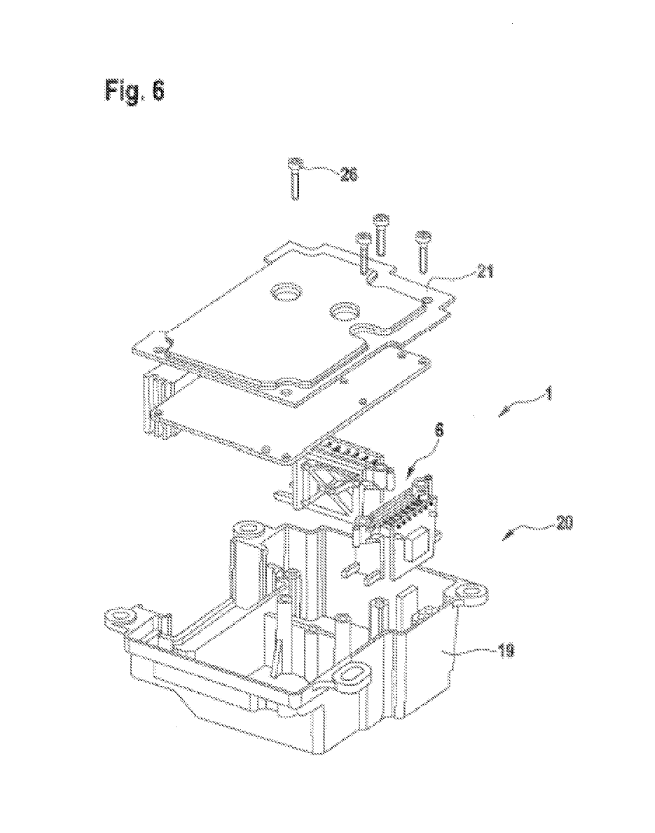

FIG. 6 shows an exploded illustration of the circuit assembly 1. It can be discerned that the housing 20 consists of a first part 19 and a second part 21, which are connected to one another by means of screws 26. The preassembled units 5—each consisting of mount 4 and second circuit board 3—are arranged in the first part 19 of the housing 20, then the first circuit board 2 is placed thereon and the housing 20 is closed. In the assembled state, that is to say with the housing 20 closed, the first circuit board 2 is pressed onto the preassembled units 5, whereby the electrical contact 6 is produced.

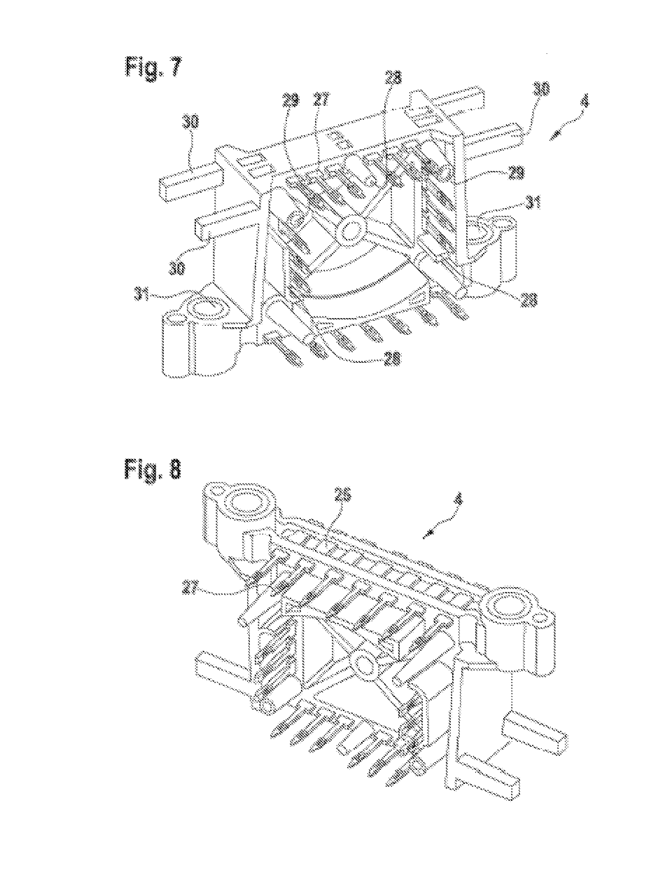

FIG. 7 shows a mount 4, without preassembled second circuit board 3. The mount 4 has a press-fit pin 27 for making contact with and for holding the second circuit board 3. Bearing areas 28 are likewise provided, on which the second circuit board 3 bears after preassembly. Insert openings 29 for receiving the holding elements 16 in a latching manner are likewise provided. The holding elements 16 are introduced into the insert openings 29 in a latching manner after the preassembly of the second circuit board 3 on the mount 4. Guide lugs 30 are provided on the mount 4, which allow accurate positioning during introduction of the mount 4 into the housing 20. The mount 4 illustrated in FIG. 7 has bushes 31, through which screws (not illustrated) can extend for the purpose of fixing the mount 4 to the first circuit board 2. In this way, the accurate positioning is provided by means of the guide lugs 30 and secure and releasable fixing to the first circuit board 2 is also provided by means of the bushes 31.

FIG. 8 shows the mount 4 known from FIG. 7 in a view from below. Contact areas 25 for the S spring elements, via which the electrical contact 6 with the first circuit board 2 is intended to be produced, are clearly discernable here. The contact areas 25 for the S spring elements are electrically connected to the press-fit pins 27, such that the electrical contact 6 between first circuit board 2 and second circuit board 3 is produced via the mount 4.

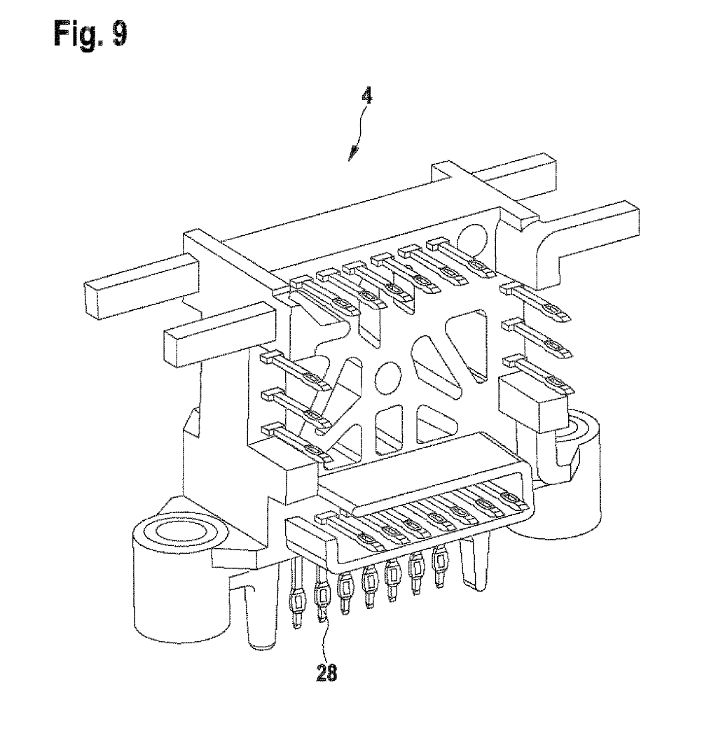

FIG. 9 shows an alternative embodiment of the mount 4 known from FIGS. 7 and 8. In contrast to FIGS. 7 and 8, the mount 4 illustrated here, for the purpose of making contact with the first circuit board 2, does not have contact areas 25 for S spring elements, but rather press-fit pins 28. In contrast to the mounts 4 illustrated in FIGS. 1 and 2, therefore, here as well the electrical contact 6 is not produced directly between first circuit board 2 and second circuit board 3, but rather via the mount 4 or the press-fit pins 28. For the further properties of the mount 4 illustrated here, reference should be made to the explanations concerning FIGS. 7 and 8.

1. An electrical circuit assembly (1), comprising a first circuit board (2), at least one second circuit board (3) and at least one mount (4) for holding the second circuit board (3) on the first circuit board (2) whilst producing an electrical contact (6) between the first (2) and the second (3) circuit board, characterized in that the second circuit board (3) is preassembled on the mount (4), and in that the preassembled unit (5) consisting of second circuit board (3) and mount (4) is connected to the first circuit board (2), wherein the mount (4) and the second circuit board (3) are arranged transversely, with respect to the first circuit board (2).

2. The electrical circuit assembly as claimed in claim 1, characterized in that the preassembled unit (5) is connected to the first circuit board (2) in a releasable manner.

3. The electrical circuit assembly as claimed in claim 1, characterized in that the connection between the first circuit board (2) and the mount (4) and/or the fixing of the second circuit board (3) to the mount (4) are/is produced by means of hot calking, screwing, clipping or press-fitting.

4. The electrical circuit assembly as claimed in claim 1, characterized in that the mount (4) is a die-cast component.

5. The electrical circuit assembly as claimed in claim 1, characterized in that the mount (4) comprises aluminum, zinc or magnesium or a plastic.

6. The electrical circuit assembly as claimed in claim 1, characterized by a housing (20), in which the first circuit board (2), the second circuit board (3) and/or the mount (4) are arranged at least in regions.

7. The electrical circuit assembly as claimed in claim 1, characterized in that the mount (4) is fixed together with the second circuit board (3) on/in a housing (20).

8. The electrical circuit assembly as claimed in claim 1, characterized in that the preassembled unit (5) is fixed on/in the housing (20) by means of screwing, clamping or adhesive bonding.

9. The electrical circuit assembly as claimed in claim 1, characterized in that at least two mounts (4) are provided, which are arranged at an angle with respect to one another.

10. The electrical circuit assembly as claimed in claim 1, characterized in that the electrical contact (6) between the first (2) and the second (3) circuit board is produced directly and/or via the mount (4).

11. The electrical circuit assembly as claimed in claim 1, characterized in that the direct contact is produced by means of a semi flexible connection, at least one press-fit pin (8), at least one spring element, a circuit board connector and/or soldering.

12. The electrical circuit assembly as claimed in claim 1, characterized in that the contact (6) via the mount (4) is produced via at least one contact element (7, 24).

13. The electrical circuit assembly as claimed in claim 1, characterized in that the contact element makes contact with the first circuit board (2) by means of at least one spring element or at least one press-fit pin (8) and with the second circuit board (3) by means of at least one press-fit pin (27).

14. A control device comprising at least one electrical circuit assembly (1) as claimed in claim 1.

15. A method for producing an electrical circuit assembly (1), as claimed in claim 1, wherein the circuit assembly (1) has a first circuit board (2), at least one second circuit board (3) and at least one mount (4) for holding the second circuit board (3) on the first circuit board (2) whilst producing an electrical contact (6) between the first (2) and the second (3) circuit board, characterized in that the second circuit board (3) is preassembled on the mount (4), and in that the preassembled unit (5) of the second circuit board (3) and the mount (4) is connected to the first circuit board (2), wherein the mount (4) and the second circuit board (3) are arranged transversely, with respect to the first circuit board (2).

16. The electrical circuit assembly as claimed in claim 1, wherein the circuit assembly is for a control device of a motor vehicle.

17. The electrical circuit assembly as claimed in claim 1, wherein the mount (4) and the second circuit board (3) are arranged at right angles with respect to the first circuit board (2).

18. The method as claimed in claim 15, wherein the mount (4) and the second circuit board (3) are arranged at right angles with respect to the first circuit board (2).

19. A method for producing an electrical circuit assembly (1), wherein the circuit assembly (1) has a first circuit board (2), at least one second circuit board (3) and at least one mount (4) for holding the second circuit board (3) on the first circuit board (2) whilst producing an electrical contact (6) between the first (2) and the second (3) circuit board, the method comprising:
preassembling the second circuit board (3) on the mount (4); and
connecting the preassembled unit (5) of the second circuit board (3) and the mount (4) to the first circuit board (2), wherein the mount (4) and the second circuit board (3) are arranged transversely with respect to the first circuit board (2).

20. The method as claimed in claim 19, wherein the mount (4) and the second circuit board (3) are arranged at right angles with respect to the first circuit board (2).
